(19) United States
(12) Patent Application Publication
(10) Pub. No.: US 2007/0082504 A1
(43) Pub. Date: Apr. 12, 2007

(54) Pre-metal dielectric semiconductor structure and a method for depositing a pre-metal dielectric on a semiconductor structure

(75) Inventors: Thomas Dittkrist, Dresden (DE); Steffen Jahne, Radebeul (DE); Arabinda Das, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/247,981

(22) Filed: Oct. 12, 2005

(51) Int. Cl. H01L 21/31; H01L 21/469; H01L 23/52; H01L 23/48; H01L 29/40

(52) U.S. Cl. 438/778; 257/751

(57) ABSTRACT

The invention refers to a pre-metal dielectric semiconductor structure comprising a substrate, having features on a surface of the substrate, wherein the features are spaced from at least one gap between the features. The gap is filled with an advantageous layer combination. The layer combination comprises at least one spin-on dielectric layer. Additionally a further insulating layer is disposed or a further silicate glass layer doped with phosphorus is arranged. Using this layer combination, the filling of the gap with less or no voids and advantageous chemical and/or mechanical and/or electrical features is attained.

### BACKGROUND OF THE INVENTION

Field of the Invention

The present invention relates to a pre-metal dielectric semiconductor structure and a method for depositing a pre-metal dielectric on a semiconductor structure.

In the manufacturing of semiconductor devices, as the dimensions have shrunk, this become more challenging to provide dielectric film layers that provide adequate electrical isolation between interconnect features and device components in order to minimize RC delay and cross talk. One method of doing this is to provide dielectric layers using materials having lower dielectric constants (low-k dielectrics) then conventional dielectric materials such as silicon dioxide (SiO₂) or silicon nitride.

In particular, at the start of the fabrication of a back end of line (BEOL) module that contains the interconnect metal levels, a dielectric layer is typically provided between the devices of features, such as gate conductor stacks, on the substrate, of front end of line (FEOL), and the first layer of metal in the interconnect level or BEOL. This dielectric layer between the device level and the interconnect level is known as the pre-metal dielectric (PMD). In example a boron-phosphor-silicate glass is used to fill up a gap between features of a semiconductor structure. The silicon dioxide with boron and phosphorus added to lower the temperature at which the glass oxide starts to flow from about 1400° C. for pure silicon oxide to about 800° C. for boron or phosphor silicate glass that is deposited by a chemical vapor deposition process.

Although films provided by spin-on deposition may adequately fill spaces or gaps, this films are usually porous and would be incompatible with the middle of line processing steps by being susceptible to problems such as shrinkage, layer cracking or thermal instability. The problem of adequate gap fill can be particularly difficult if the aspect ratio which is the ratio of height to width of the gaps, is above about 1.0.

For forming a pre-metal dielectric gap fill on a semiconductor substrate by a chemical vapor deposition method it is known by the U.S. patent U.S. Pat. No. 6,531,412 B2 to use a thermal sub-atmospheric chemical vapor deposition process which includes a carbon-containing organometallic or organosilicon precursor, ozon, and a source of dopants. The carbon-containing organometallic or organosilicon precursors may include a cyclosiloxane such as tetramethylcyclotetrasiloxane or other cyclic siloxanes. A phosphorus dopant is added to getter alkalimetals such as sodium and potassium. In addition to phosphorus, a dopant is added that allows the film to reflow relatively easily at a temperature and process time that will not lead to thermal damage. As the aspect ratio increases, the formation of voids become more likely, and better reflow may be necessary.

### SUMMARY OF THE INVENTION

It is an object of the present invention to provide a pre-metal dielectric semiconductor structure with an improved homogeneity. It is a further object of the present invention to provide a pre-metal dielectric semiconductor structure with less voids. Furthermore it is another object of the present invention to provide a method for depositing a pre-metal dielectric on a semiconductor structure that may be used for filling up high aspect ratio structures in a reduced process time. A further object of the present invention is to provide a pre-metal dielectric on a semiconductor structure with a reduced influence of dopants on electrical devices that are integrated in the substrate.

One or several of these and other objects are achieved by the present invention.

The present invention is a pre-metal dielectric semiconductor structure comprising a substrate having features on a surface of the substrate, wherein the features are spaced to form at least one gap between the features, wherein the gap is filled with at least a first and a second layer, wherein the first layer is arranged on the substrate and constituted as a liner layer, wherein the second layer is made of a spin-on dielectric and arranged on the first layer.

Furthermore the present invention is a pre-metal dielectric semiconductor structure comprising a substrate having features on a surface of the substrate, wherein the features are spaced to form at least one gap between the features, wherein the gap is filled with a first layer, wherein the first layer is a spin-on dielectric layer, wherein a second layer is deposited on the first layer, wherein the second layer is boron-phosphorus-silicate glass deposited on the first layer.

Furthermore, the present invention is pre-metal semiconductor structure comprising a substrate having features on a surface of the substrate, wherein the features are spaced to form at least one gap between the features, wherein the gap is filled with a first layer deposited on the substrate, wherein the first layer is a phosphorus doped silicate glass, wherein a second layer is deposited on the first layer, wherein the second layer is a spin-on dielectric layer.

Furthermore, the present invention is a method for depositing a pre-metal dielectric on a semiconductor structure, whereby a semiconductor substrate is disposed having features on a surface of the substrate, whereby the features are spaced to form at least one gap between the features, whereby the gap is filled with a first and a second layer, whereby the first layer is a liner, that is deposited on the substrate, whereby the second layer is a spin-on dielectric layer that is deposited on the first layer.

The present invention is based on the idea to provide a pre-metal dielectric semiconductor structure with improved gap filling properties that may particularly be of advantage for a memory device in example for a dynamic random access memory.

The present invention is furthermore based on the idea to provide a pre-metal dielectric fill for a gap between two proximate gate contacts and especially between two gate bit contacts.

The present invention provides the advantage to provide a pre-metal dielectric fill for a semiconductor structure with improved properties that may be used for filling up gaps with high aspect ratio in example for filling up a gap between two bit contacts of a memory device.

### BRIEF DESCRIPTION OF THE DRAWINGS

These and other objects and features of the present invention will become clear from the following description taken in conjunction with the accompanying drawings in which:

FIG. 1 is a schematic view of a semiconductor structure with a pre-metal dielectric fill;

FIG. 2 is a schematic view of a semiconductor structure with a first and a second layer;

FIG. 3 is a schematic view of the semiconductor structure of FIG. 2 filled with dielectric material;

FIG. 4 depicts a semiconductor structure partially filled with a spin-on dielectric layer; and

FIG. 5 depicts the structure of FIG. 4 covered with a further layer of BPSG-glass.

### DESCRIPTION OF THE PREFERRED EMBODIMENTS

In the following descriptions of embodiments of the invention, a pre-metal dielectric semiconductor structure and a method for depositing a pre-metal dielectric on a semiconductor structure will be detailed. It will be appreciated that this is intended as examples only, and that the invention may be practiced under variety of conditions and using a variety of embodiments.

The invention will be described using a semiconductor structure comprising a substrate 1 of silicon or any other semiconductor material in example gallium arsenide. The substrate 1 comprises as features gate stacks 2, 3, 4 that are disposed on a surface 5 of the substrate 1. The gate stacks 2, 3, 4 comprise at sidewalls space elements 6. The space elements 6 may be formed of silicon nitride and cover sidewalls of the gate stacks 2. The gate stack may comprise a gate electrode and a gate dielectric layer that is disposed between the gate electrode and the surface 5 of the substrate 1. The gate electrode may be constituted by polysilicon and the gate dielectric layer may be constituted by a high-k material.

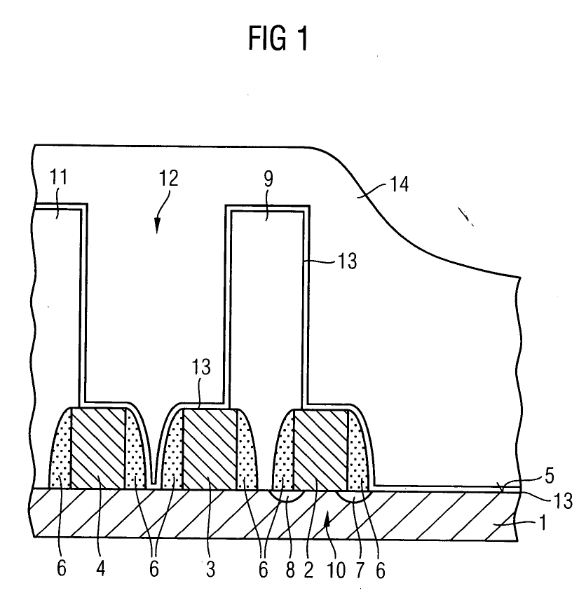

The gate stacks 2, 3, 4 may constitute control contacts of electronic devices in example transistors that are integrated in the substrate 1. Source and drain regions 8, 7 of the transistors are disposed adjacent to the surface 5 of the substrate 1 and at least partially at opposite sides under one gate stack 2. A drain region 7 and a source region 8 are disposed under the first gate stack 2. The drain and source regions of the other gate stacks 3, 4 are not depicted in FIG. 1.

Between the first and the second gate stack 2, 3 a bit contact 9 is arranged. The bit contact 9 extends from the surface 5 of the substrate 1 between the first and the second gate stack 2, 3 until a given height above the first and the second gate stack 2, 3. The bit contact 9 may be formed of polysilicon and the bit contact 9 is electrically connected with the source region 8 of a first transistor 10. The drain contact 7 is connected with an electrical element i.e. a capacitor disposing a memory all of a memory device. A further bit contact 11 is disposed between the fourth gate stack 4 and a further not shown gate stack. The first and the second bit contact 9, 11 have a similar shape and between the two bit contacts 9, 11 a gap 12 is disposed. The gap 12 extends down between two space elements 6 of the second and third gate stack 3, 4 to the surface 5 of the substrate 1.

The surface of the structure is covered with a liner 13. The liner 13 covers the whole surface with the surface of the substrate 1, free surface of the spacer element 6, free surface of the gate stacks 2, 3, 4 and free surface of the first and the second bit contact 9, 11. The liner 13 constitutes an insulating layer made of in example silicon nitride, silicon oxide or silicon oxynitride. The structure is filled up with a spin-on dielectric 14 that is deposited on the liner 13 covering the whole surface of the structure.

A great variety of spin-on dielectric materials are known in example silesquioxane (SSQ)-based materials, silicate-based materials, organic polymers and amorphous carbon. Furthermore spin-on glasses may be used as spin-on dielectric for filling up the structure. For depositing, the spin-on dielectric is poured on the surface of the structure and the structure is rotated until the spin-on dielectric is uniformly distributed over the surface of the structure. Using the spin-on dielectric it is possible to fill up the structure at room temperature. To stabilize the spin-on dielectric, a temperature process is performed heating up the spin-on dielectric to about 400° C. with a steam ambient. Additionally, in a further temperature process the spin-on dielectric is heated up to 550° C. in a nitrogen ambient and cured out. In a following process step, the surface of the spin-on dielectric 14 is planarized by a chemical mechanical polishing step (CMP). In further process steps, the bit contacts 9, 11 are opened from the top and electrically connected with bit lines. In following process steps, the structure may be completed to a dynamic random access memory. In this example, an insulating liner and a spin-on dielectric is used for filling up gaps with high aspect ratios. In the discussed embodiment, a gap is used between two contact bits of a memory device, however the use of the insulating liner and the spin-on dielectric as filling material for high aspect ratio gaps is not limited to this embodiment, but may be used in any device or substrate structure disposing gaps.

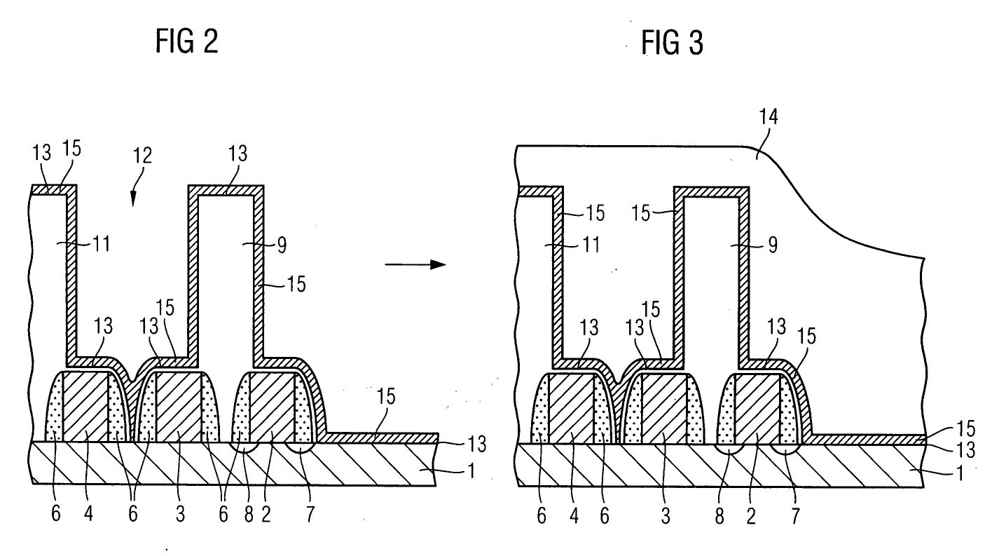

FIG. 2 depicts another embodiment with a substrate 1, gate stacks 2, 3, 4 with spacer elements 6 and bit contacts 9, 11, whereby the surface of the structure is covered by an insulating liner 13. The insulating liner 13 may be formed of silicon oxide or silicon nitride. The liner 13 is covered with a phosphorus silicate glass (PSG) layer 15. The PSG layer 15 covers the surface of the structure and shows a small height compared to the height of the gap 12 arranged between the first and the second bit contact 9, 11. The PSG liner 15 may be deposited by a chemical vapor deposition at a pressure of about 200 Torr and a temperature of about 480° C. The thickness of the PSG liner 15 may be smaller than 50 nm, preferably in the region of 25 nm. Additionally, the silicate glass may comprise about 5 weight percent of phosphorus. The liner 13 may have a thickness of about 5 to 10 nm.

In a following process step, a spin-on dielectric 14 is deposited on the structure as shown in FIG. 3. For depositing the spin-on dielectric the same process steps are used as for depositing the spin-on dielectric of FIG. 1. The thickness of the spin-on dielectric may be in the region of 600 nm. After pouring and equally distributing the spin-on dielectric on the structure, two temperature process steps are used for stabilizing the spin-on dielectric 14. At a first temperature process the spin-on dielectric 14 is heated up to 400° C. in a steam ambient. In a second process, the spin-on dielectric is heated up to 550° C. in a nitrogen ambient and cured out.

In this embodiment a filling is used for the structure and particularly for the gap 12 comprising as a first layer an insulating liner 13, as a second layer a PSG liner 15 and as a third layer a spin-on dielectric 14. Depending on the embodiment, the insulating liner 13 may be omitted and the PSG liner 15 is directly deposited on the surface of the structure. The surface of the spin-dielectric 14 may be processed in further steps and the structure may be completed to a DRAM connecting the bit contacts 9, 11 with bit lines. The spin-on dielectric 14 may be planarized by a chemical mechanical polishing process. The example of FIGS. 2 and 3 explains the filling of a gap 12 of semiconductor structure with an insulating liner 13, a PSG liner 15 and a spin-on dielectric 14. The insulating liner 13 formed i.e. of silicon nitride and the PSG liner 15 have the function to improve the interface between the spin-on dielectric 14 and the substrate 1, whereby particularly the PSG liner 15 getters alkali elements such as sodium. Therefore, the isolation is sufficient although sodium is available.

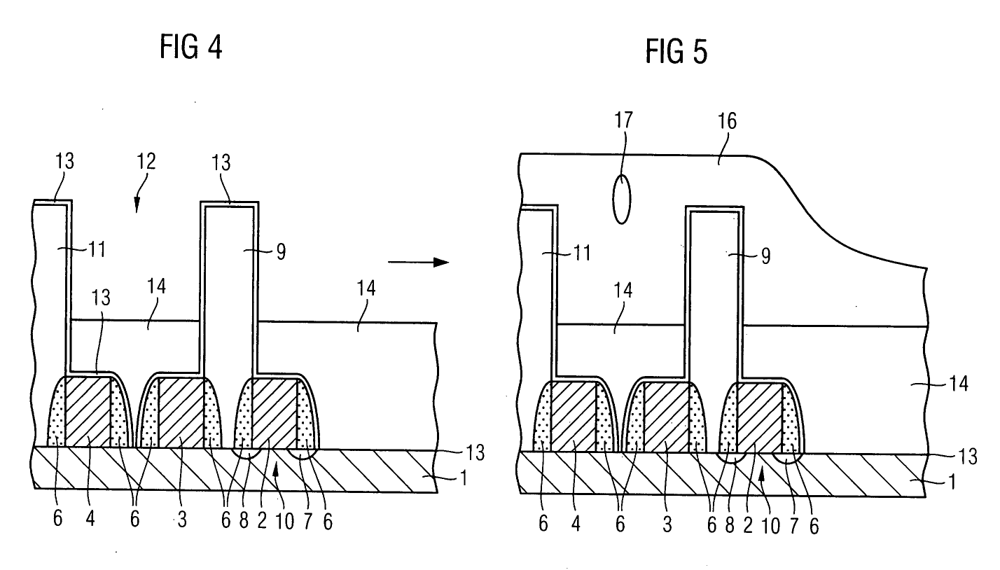

FIGS. 4 and 5 depict two process steps of another embodiment that uses for filling up a gap of a semiconductor structure with a gap 12 using as a first fill spin-on dielectric 14 for reducing the aspect ratio of the gap 12 and completing the fill with a boron-phosphorus-silicate glass 16. This process has the advantage that the gap 12 is partially filled with the spin-on dielectric 14 that can easily be filled in gaps 12 also with a high aspect ratio with a short process time. However, the mechanical and/or chemical properties of the spin-on dielectric 14 may not be sufficient. Therefore an upper part of the gap 12 is filled with the BPSG layer 16. Because of the lower aspect ratio of the partially filled gap 12, less and/or smaller voids 17 are produced by filling up the gap 12 with the BPSG layer 16. Additionally, the voids 17 are closed or reduced in volume by a curing and annealing process of the BPSG layer 16.

FIG. 4 depicts a sectional view of a part of a semiconductor structure with a substrate 1 in example a semiconductor wafer with memory cells, transistors 10 and gate stacks 2, 3, 4 that are arranged on a surface of the substrate 1. Electronic devices as transistors and capacitors may be disposed in the substrate 1. The substrate 1 and the semiconductor structure will be processed to a DRAM memory. The gate stacks 2, 3, 4 comprise at opposite side faces spacer elements 6. Between the first and the second gate stack 2, 3 a first bit contact 9 is guided to the surface of the substrate 1. The first bit contact 9 is electrically connected to a transistor that may be switchable by the first and/or the second gate 2, 3. A second bit contact 11 is arranged that is disposed between the third gate stack 4 and a further, not shown, gate stack. Also the second bit contact 11 is disposed as an electrical contact to an electronic device in example a transistor. The free surface of the substrate 1, the free surface of the spacer element 6 and the free surface of the first, the second and the third gate stack 2, 3, 4 and the free surface of the first and the second bit contact 9, 11 are covered with an insulating liner 13 in example a nitride liner or a silicon oxide liner. On the insulating liner 13 a spin-on dielectric 14 is deposited. Between the first and the second bit contact 9, 7 a gap 12 is arranged that is partially filled with the spin-on dielectric 14. The spin-on dielectric 14 is filled up to a level higher than the top of the gate stacks 2, 3, 4. The spin-on dielectric is poured on the surface of the semiconductor structure and equally distributed by rotating the substrate 1. Then the spin-on dielectric 14 is processed with a temperature of about 400° C. in an oxidising ambient. Additionally in a second temperature process the spin-on dielectric 14 is heated up to 550° C. in an inert ambient. With the spin-on dielectric 14 the aspect ratio of the gap 12 is reduced and the gap 12 is transformed to a lower gap as shown in FIG. 4. With this first filling step, the aspect ratio of the gap 12 is reduced and with a second layer made of boron-phosphorus-silicate glass (BPSG) 16 the gap 12 can be filled up. Because of the lower aspect ratio of the gap 12, the BPSG layer 16 can be deposited with less or smaller voids 17 as shown in FIG. 5. The BPSG layer 16 is deposited with a sub-atmospheric thermal chemical vapor deposition (SACVD) using a temperature of about 500° C. with a pressure of about 200 Torr with a low deposition rate. The thickness of the BPSG layer 16 may be about 600 nm. The BPSG layer 16 may comprise for example about 5 weight percent of boron and about 4.4 weight percent of phosphorus. If a void 17 might be produced because of the high aspect ratio of the partially filled up gap 12 between the first and the second bit contact 9, 11, the void 17 may be removed by a post-annealing process or at least the volume of the void 17 may be reduced by the post-anneal process. Therefore it might be desirable to use a post-deposition reflow step at a low reflow temperature to fill voids left of the reposition of the BPSG layer 16 with minimal heat treatment to avoid thermal damage. Additionally, the concentration of the boron and phosphorus dopant may be changed for lowering the temperature required to reflow the SPSG layer 16.

Therefore, depending on the embodiment the concentration of the boron and the concentration of phosphorus may be changed.

In further process steps, the surface of the BPSG layer 16 may be planarized by a chemical mechanical polishing process. Additionally, the first and the second bit contacts 9, 11 may be connected with bit lines and the DRAM memory may be fabricated with further process steps.

The invention was explained using examples for producing a memory device, particularly for filling up a gap 12 between two gate stacks 3, 4 and to bit contacts 9, 11. However, the invention may be used in any technical field in which a gap, especially a gap with a high aspect ratio, has to be filled with an insulating layer, especially a dielectric material. Therefore, the invention may also be used in any application of nanotechnology.

Depending on the embodiment, the gap 12 may also be totally filled in a first step with the spin-on dielectric 14 and in a following step recessed to a predetermined level providing a further gap between the first and the second bit contact 9, 11. For recessing the spin-on dielectric a wet or a dry etching chemistry may be used.

Depending on the embodiment, the insulating liner 13 in the examples of FIGS. 2, 3, 4, 5 may be omitted. Therefore, a basic idea of the invention is to fill up gaps with a high aspect ratio with an at least two layer fill. One of the two layers comprises a phosphorus doped silicate glass for gettering ions, particularly for gettering sodium ions. Depending on the embodiment, a first layer directly deposited on the surface of the structure is formed of the phosphorus silicate glass and the second layer arranged on the first layer is the spin-on dielectric. In another combination, the first layer is formed of the spin-on dielectric and the second layer, arranged on the first layer, is formed of a phosphorus doped silicate glass, particularly by a boron-phosphorus-silicate glass layer. These combinations have the advantage to provide a fill material for filling up gaps with high aspect ratio without or at least with less and/or smaller voids in the fill material. Additionally, a barrier layer comprising phosphorus is disposed gettering ions, in example sodium, improving the electrical quality of the semiconductor structure.

1. A pre-metal dielectric (PMD) semiconductor structure comprising:
a substrate having features on a surface of the substrate, wherein the features are spaced to form at least one gap between the features, wherein the gap is filled with a first and a second layer on the substrate, wherein the first layer is a liner and arranged on the substrate, wherein the second layer is a spin-on dielectric layer and arranged on the first layer.

2. The PMD structure of claim 1, wherein a layer of a boron and phosphorus doped glass is arranged on the spin-on dielectric layer.

3. The PMD structure of claim 1, wherein the first layer comprises silicon nitride or silicon oxynitride.

4. The PMD structure of claim 3, wherein a phosphorus doped glass layer is arranged between the liner and the spin-on dielectric layer.

5. The PMD structure of claim 1, wherein the first layer comprises phosphorus doped glass.

6. The PMD structure of claim 1, wherein the features comprise gate stacks.

7. The PMD structure of claim 1, wherein the features comprise gate stacks and bit contacts, wherein a bit contact is arranged between two proximate gate stacks, wherein two bit contacts are arranged disposing the gap.

8. A pre-metal dielectric (PMD) semiconductor structure comprising:
a substrate having features on a surface of the substrate, wherein the features are spaced to form at least one gap between the features, wherein the gap is partially filled with a first layer, wherein the first layer is a spin-on dielectric layer, wherein a second layer is deposited on the first layer, wherein the second layer is a boron-phosphorus-silicate glass layer.

9. The PMD structure of claim 8, wherein an insulating layer is disposed under the first layer.

10. A pre-metal dielectric (PMD) semiconductor structure comprising:
a substrate having features on a surface of the substrate, wherein the features are spaced to form at least one gap between the features, wherein the gap is filled with a first layer deposited on the substrate, wherein the first layer is a phosphorus doped silicate glass layer, wherein a second layer is deposited on the first layer, wherein the second layer is a spin-on dielectric layer.

11. The PMD structure of claim 9, wherein an insulating layer is arranged in the gap under the first layer.

12. Method for depositing a pre-metal dielectric (PMD) on a semiconductor structure according to claim 1 comprising:
disposing a substrate having features on a surface of the substrate, wherein the features are spaced to form at least one gap between the features;
filling the gap with a first and second layer, whereby the first layer is a liner that is deposited on the substrate, whereby the second layer is a spin-on dielectric layer that is deposited on the first layer.

13. Method according to claim 12, wherein a layer of a boron and phosphorus doped glass is deposited on the spin-on dielectric layer.

14. Method according to claim 12, wherein the liner is a silicon nitride layer, wherein a phosphorus doped glass layer is deposited on the liner and the spin-on dielectric layer is deposited on the phosphorus doped glass layer.

15. Method according to claim 12, wherein the first liner layer is a phosphorus doped glass layer deposited on the substrate and the second layer of spin-on dielectric is deposited on the phosphorus doped glass layer.

16. Method according to claim 12, wherein a nitride layer is deposited on the substrate and a spin-on dielectric layer is deposited on the nitride layer.

17. Method according to claim 12, wherein the features comprise gate stacks of transistors and the spin-on dielectric is deposited between the gate stacks.

18. Method according to claim 12, wherein the features comprise gate stacks and bit contacts, wherein a bit contact is arranged between two proximate gate stacks, wherein two bit contacts are arranged and the spin-on dielectric layer is deposited between the bit contacts and the gate stacks.
